(19) United States
(12) Patent Application Publication
(10) Pub. No.: US 2025/0212414 A1
(43) Pub. Date: Jun. 26, 2025

(54) FERROELECTRIC STORAGE DEVICE AND METHOD FOR MANUFACTURING SUCH A DEVICE

(71) Applicant: COMMISSARIAT A L'ENERGIE ATOMIQUE ET AUX ENERGIES ALTERNATIVES, PARIS (FR)

(72) Inventors: Julien BORREL, GRENOBLE CEDEX (FR); Justine BARBOT, GRENOBLE CEDEX (FR); Jean COIGNUS, GRENOBLE CEDEX (FR); Laurent GRENOUILLET, GRENOBLE CEDEX (FR)

(21) Appl. No.: 18/990,469

(22) Filed: Dec. 20, 2024

(30) Foreign Application Priority Data
Dec. 21, 2023 (FR) 2314855

(51) Int. Cl. H10B 51/20

(52) U.S. Cl. CPC H10B 51/20

(57) ABSTRACT

A ferroelectric storage device including a first layer, a second layer and a layer of ferroelectric material extending between the first layer and the second layer, the layer of ferroelectric material including a first part having a first thickness and a second part having a second thickness, the first thickness and the second thickness being distinct.

### CROSS-REFERENCE TO RELATED APPLICATIONS

This application claims priority to French Patent Application No. 2314855, filed Dec. 21, 2023, the entire content of which is incorporated herein by reference in its entirety.

### FIELD

The present invention generally relates to the field of microelectronics. It relates more particularly to the field of non-volatile memories.

In particular, the invention relates to a ferroelectric storage device. It also relates to a method for manufacturing such a ferroelectric storage device.

### BACKGROUND

The main quality of FeRAM (Ferroelectric Random Access Memory)-type ferroelectric memories is that they are non-volatile, i.e. they retain the information stored even when the voltage is turned off. They also have the advantage of consuming little energy and having low write and read times relative to other types of non-volatile memory such as FLASH memory.

Ferroelectric memories of the FeRAM type generally take the form of a stack in which a layer of ferroelectric material is positioned between two metal electrodes. Ferroelectric memories are capacitive type memories with two remanent polarisation states, +Pr and −Pr. The operation of these ferroelectric memories is based on the ferroelectric properties of the ferroelectric material placed between two metal electrodes.

More particularly, as regards the operation of FeRAM type ferroelectric memories, by the application of a potential difference between the two electrodes creating an electric field having a value greater than a positive coercive field +Ec, the ferroelectric memory is placed in a high remanent polarisation state +Pr and by the application of a potential difference creating an electric field having a value less than the negative coercive field −Ec, the ferroelectric memory is placed in a low remanent polarisation state −Pr.

The high remanent polarisation state +Pr then corresponds to the binary logic state ‘0’ and the low remanent polarisation state −Pr to the binary logic state ‘1’, which allows information to be stored.

Furthermore, when the application of the potential difference between the two metal electrodes is stopped, the remanent polarisation state remains: this explains the non-volatile nature of ferroelectric memories.

For reading, it is assumed that the memory is in a given state and a voltage is applied. This voltage is for example positive, greater than the voltage creating an electric field with a value greater than the positive coercive field +Ec. Thus, if the memory was already in the high remanent polarisation state +Pr, this polarisation state is unchanged and no current spike is observed (or a very small current spike may be observed). Conversely, if the memory was in the low remanent polarisation state −Pr, a much larger current peak is observed.

The consequence of this read operation is that it destroys the polarisation state.

Ferroelectric Tunnel Junction (FTJ) memories are also known. FTJ-type ferroelectric memories generally take the form of a stack in which a layer of ferroelectric material is positioned between two metal electrodes. FTJ ferroelectric memories are resistive type memories with two opposite polarisation states for the layer of ferroelectric material. The operation of these ferroelectric memories is based on ferroelectric properties of the ferroelectric material placed between two metal electrodes.

More particularly, as regards the operation of FTJ-type ferroelectric memories, the two polarisation states respectively correspond to two different resistance levels: a high-resistance level, corresponding for example to a high polarisation state +Pr, and a low-resistance level, corresponding to a low polarisation state −Pr. By way of example, the low-resistance level has an electrical resistance approximately one thousand times lower than that of the high-resistance level.

In the case of FTJ-type ferroelectric memories, the read operation comprises the application of a read voltage −Vr. The read voltage −Vr is, for example, negative and lower in absolute value than a voltage Vc associated with the coercive field. This enables non-destructive reading to be carried out by measuring a tunnel current.

In order to increase memory density, it is known to implement a so-called “multi-level” storage. This “multi-level” storage is associated with different polarisation states, on which it will be possible to store information.

Document “Multilevel data storage memory using deterministic polarization control.” by Lee, Daesu et al. in Advanced materials, vol. 24 (3), 2012, 402-406, doi: 10.1002/adma.201103679 describes a FeRAM-type ferroelectric memory with several storage levels. In this example, as is represented in FIG. 1 (representing the course of the polarisation P as a function of the applied voltage V), the memory can be placed in several intermediate remanent polarisation states Pr₁, Pr₂, Pr₃, Pr₄, Pr₅, Pr₆, Pr₇ (Pr₁ corresponding to the state 0 of low polarisation). It will therefore be possible to store information at different levels. Thanks to this “multi-level” storage, it is possible to code several states per memory (here, in the example, eight states are coded), whereas in a standard cell only two states are accessible (states 0 or 1 only). Thus, the information contained in a memory with “multi-level” storage is equivalent to that contained in several standard memories.

In practice, in this example, to implement this storage on the different intermediate levels, each intermediate polarisation state Pr₁, Pr₂, Pr₃, Pr₄, Pr₅, Pr₆, Pr₇ is associated with a corresponding current. Thus, upon application of a voltage between the electrodes, an associated ferroelectric current is read. This current then makes it possible to identify the intermediate polarisation state Pr₁, Pr₂, Pr₃, Pr₄, Pr₅, Pr₆, Pr₇ concerned and therefore to deduce the information initially stored in this intermediate polarisation state Pr₁, Pr₂, Pr₃, Pr₄, Pr₅, Pr₆, Pr₇ of the ferroelectric memory.

However, some drawbacks are observed in such high-density memories. For example, it can be difficult to distinguish between two intermediate polarisation states that are close to each other. Indeed, an overlap between the different intermediate polarisation states may be encountered. In such a case, the application of a voltage (between the electrodes) to this overlap zone does not allow the associated current, and therefore the intermediate remanent polarisation state associated therewith, to be deduced with some certainty.

### SUMMARY

One or more aspects of the present invention therefore aim to improve high-density ferroelectric storage devices by allowing unambiguous distinction between different polarisation states.

An aspect of the invention then relates to a ferroelectric storage device comprising a first layer, a second layer and a layer of ferroelectric material extending between the first layer and the second layer,

the layer of ferroelectric material comprises a first part having a first thickness and a second part having a second thickness, the first thickness and the second thickness being distinct.

Thus, the layer of ferroelectric material in the ferroelectric storage device according to an aspect of the invention has a non-uniform thickness. This variability in thickness leads to non-uniformity in the ferroelectric properties of the ferroelectric storage device. This non-uniformity of properties especially makes it possible to increase differences between the voltage ranges to be applied to store information in the different intermediate polarisation states.

Indeed, the different thicknesses mean that, for a given (write) voltage, the electric field is greater in regions of lower thickness. In other words, to write information in an intermediate polarisation state associated with a low thickness, a higher voltage has to be applied. The differences in thickness therefore lead to differences in the voltages to be applied to encode information in the different intermediate polarisation states.

The different thicknesses used are therefore associated with different intermediate polarisation states in the ferroelectric storage device.

In other words, by virtue of the non-uniformity created in the layer of ferroelectric material (due to thickness variability), differences between the intermediate polarisation states are created.

Further to the characteristics just discussed in the preceding paragraphs, the ferroelectric storage device according to one aspect of the invention may have one or more additional characteristics from among the following, considered individually or according to any technically possible combinations:
the first layer has a constant thickness;
the device comprises a support layer having a cavity, the cavity comprising a bottom wall and a side wall, the side wall forming a tilt angle relative to a direction normal to the bottom wall, the first layer, the second layer and the layer of ferroelectric material being positioned in the cavity;
a ratio of the second thickness to the first thickness is between 2 and 4;
the first thickness is between 3 and 7 nanometers and the second thickness is between 12 and 17 nanometers;
the first part of the layer of ferroelectric material has a surface area of at least 15% of the total surface area of the layer of ferroelectric material;
the layer of ferroelectric material comprises hafnium dioxide or hafnium dioxide doped with a doping element or an alloy HfₓZr₁₋ₓO₂, where 0<x<1;
the first layer comprises a metal material;
the metal material included in the first layer is selected from tungsten, titanium nitride and tantalum nitride;
the first layer comprises a first sub-layer and a second sub-layer, the second sub-layer being disposed on the first sub-layer;
the material of the first sub-layer is selected from titanium nitride, tantalum nitride or tungsten;
the first layer comprises a semiconductor material;
the semiconductor material included in the first layer is silicon;
the material of the second sub-layer is selected from titanium, tantalum or hafnium;
the second layer comprises a metal material;
the metal material included in the second layer is selected from tungsten, titanium nitride and tantalum nitride;
the second layer comprises another first sub-layer and another second sub-layer, the other second sub-layer being disposed on the other first sub-layer;
the material of the other first sub-layer is selected from titanium, tantalum or hafnium;
the material of the other second sub-layer is selected from titanium nitride, tantalum nitride or tungsten;
the second layer comprises a semiconductor material;
the semiconductor material included in the second layer is silicon;
the cavity comprises a U-shaped profile, the first layer, the second layer and the layer of ferroelectric material being positioned in the cavity so that the first layer, the second layer and the layer of ferroelectric material have a similar shape profile to the cavity with a U-shaped profile;
the first tilt angle is between 13 and 50 degrees, for example between 15 and 35 degrees;
the second part of the layer of ferroelectric material is positioned on the bottom wall of the cavity with a U-shaped profile and the first part of the layer of ferroelectric material is positioned on the side wall of the cavity with a U-shaped profile;
the side wall comprises a first portion and a second portion, the first portion forming said first tilt angle relative to the direction normal to the bottom wall, the second portion forming a second tilt angle relative to the direction normal to the bottom wall;
the second tilt angle is greater than said first tilt angle;
the second tilt angle is between 15 and 70 degrees, for example between 20 and 40 degrees;
the layer of ferroelectric material comprises a third part having a third thickness, the third thickness being distinct from the first thickness and the second thickness, the second portion of the layer of ferroelectric material being positioned on the bottom wall of the cavity, the first part of the layer of ferroelectric material being positioned on the first portion of the side wall of the cavity, and the third part of the layer of ferroelectric material being positioned on the second portion of the side wall of the cavity;
the contact surface between the first layer and the layer of ferroelectric material is parallel to the contact surface between the first layer and the cavity; and
the first layer forms a first electrode, the second layer forms a second electrode and the layer of ferroelectric material forms a memory layer.

An aspect of the invention also relates to a method for manufacturing a ferroelectric storage device comprising the steps of:
depositing a first layer,
depositing a layer of ferroelectric material, the layer of ferroelectric material comprising a first part having a first thickness and a second part having a second thickness, the first thickness and the second thickness being distinct, and
depositing a second layer, the layer of ferroelectric material extending between the first layer and the second layer.

Further to the characteristics just discussed in the preceding paragraphs, the manufacturing method according to another aspect of the invention may have one or more additional characteristics from among the following, considered individually or according to any technically possible combinations:
the first layer has a constant thickness;
depositing the first layer is implemented by sputtering or by chemical vapour deposition;
depositing the second layer is implemented by sputtering or by chemical vapour deposition;
there is provided, before the step of depositing the second layer, a step of removing a portion of the layer of ferroelectric material, the first part of the layer of ferroelectric material being formed at a remaining portion associated with said portion removed;
the removal step is implemented by photolithography;
depositing the layer of ferroelectric material is conformally implemented;
depositing the layer of ferroelectric material is implemented by an atomic layer deposition method or by chemical vapour deposition;
there is provided, before the step of depositing the second layer, a step of implanting a doping element in the layer of ferroelectric material so as to dope the layer of ferroelectric material with the doping element;
there is provided, after the step of depositing the second layer, a planarisation step so as to make the surface of the second layer uniform;
there is provided, before the step of depositing the first layer, steps of:
   a) providing a support layer, and
   b) forming a cavity in the support layer, the cavity comprising a bottom wall and a side wall, the side wall forming a first non-zero tilt angle relative to a direction normal to the bottom wall,
   depositing the first layer, the layer of ferroelectric material and the second layer being implemented in the cavity formed,
   the second part of the layer of ferroelectric material being positioned on the bottom wall of the cavity, and the first part of the layer of ferroelectric material being positioned on the side wall of the cavity;
the first tilt angle is between 13 and 50 degrees, for example between 15 and 35 degrees;
forming the cavity is implemented by isotropic etching;
forming the cavity is implemented by wet chemical etching;
the side wall of the cavity comprising a first portion and a second portion, the first portion forming said first tilt angle relative to the direction normal to the bottom wall, the second portion forming a second tilt angle relative to the direction normal to the bottom wall, there is provided a step of forming the second portion of the cavity, the layer of ferroelectric material comprising a third part having a third thickness, the third thickness being distinct from the first thickness and the second thickness, the second part of the layer of ferroelectric material being positioned on the bottom wall of the cavity, the first part of the layer of ferroelectric material being positioned on the first portion of the side wall of the cavity, and the third part of the layer of ferroelectric material being positioned on the second portion of the side wall of the cavity;
depositing the layer of ferroelectric material is non-conformally implemented;
forming the second portion of the cavity is implemented by wet chemical etching;
the contact surface between the first layer and the layer of ferroelectric material is parallel to the contact surface between the first layer and the cavity; and
the second tilt angle is greater than the first tilt angle.

### BRIEF DESCRIPTION OF THE FIGURES

Further characteristics and benefits of the invention will become clearer from the description thereof given below, by way of indicating and in no way limiting purposes, with reference to the appended figures, wherein:

FIG. 1 illustrates the different intermediate polarisation states in the case of a FeRAM-type ferroelectric memory with several storage levels,

FIG. 2 schematically represents a first example of a ferroelectric storage device in accordance with the invention,

FIG. 3 represents, in the form of a flow chart, an example of the method for manufacturing the ferroelectric storage device of FIG. 2,

FIG. 4 illustrates step E4 of the manufacturing method represented in FIG. 3,

FIG. 5 illustrates step E6 of the manufacturing method represented in FIG. 3,

FIG. 6 illustrates step E8 of the manufacturing method represented in FIG. 3,

FIG. 7 illustrates step E10 of the manufacturing method represented in FIG. 3,

FIG. 8 schematically represents a second example of a ferroelectric storage device in accordance with the invention,

FIG. 9 represents, in the form of a flow chart, an example of the method for manufacturing the ferroelectric storage device of FIG. 8,

FIG. 10 illustrates step E102 of the manufacturing method represented in FIG. 9,

FIG. 11 illustrates step E104 of the manufacturing method represented in FIG. 9,

FIG. 12 illustrates step E106 of the manufacturing method represented in FIG. 9,

FIG. 13 illustrates step E108 of the manufacturing method represented in FIG. 9,

FIG. 14 schematically represents a third example of a ferroelectric storage device in accordance with the invention,

FIG. 15 represents, in the form of a flow chart, an example of the method for manufacturing the ferroelectric storage device of FIG. 14,

FIG. 16 illustrates step E202 of the manufacturing method represented in FIG. 15,

FIG. 17 illustrates step E204 of the manufacturing method represented in FIG. 15,

FIG. 18 illustrates step E206 of the manufacturing method represented in FIG. 15, and

FIG. 19 illustrates step E208 of the manufacturing method represented in FIG. 15.

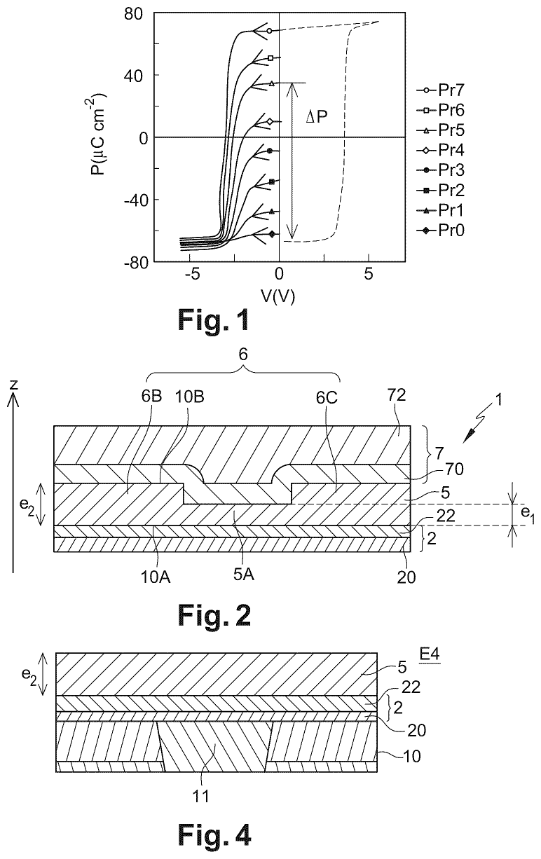

For greater clarity, identical or similar elements are identified by identical reference signs throughout the figures.

### DETAILED DESCRIPTION

The present invention aims to improve the manufacture of ferroelectric storage devices. In particular, the present invention relates to a high-density storage device wherein several polarisation states are used to store information. The present invention then aims to improve the definition of the polarisation states so as to be able to clearly distinguish between them in order to then be able to read the stored piece of information associated with each of the polarisation states.

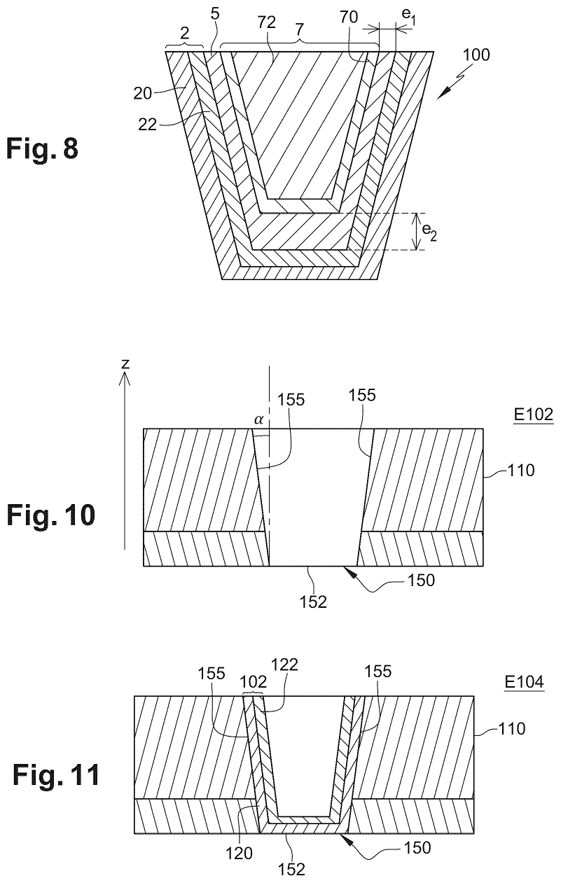

FIGS. 2, 8 and 14 each represent a ferroelectric storage device 1; 100; 200 in accordance with an embodiment of the invention. FIG. 2 represents the ferroelectric storage device 1 according to a first embodiment. FIG. 8 represents the ferroelectric storage device 100 according to a second embodiment. FIG. 14 represents the ferroelectric storage device 200 according to a third embodiment.

Regardless of the embodiment, as is visible in FIGS. 2, 8 and 14, the ferroelectric storage device 1; 100; 200 comprises a first layer 2; 102; 202, a second layer 7; 107; 207 and a layer of ferroelectric material 5; 105; 205 which is disposed between the first layer 2; 102; 202 and the second layer 7; 107; 207.

As is visible in FIGS. 2, 8 and 15, the device 1; 100; 200 is in the form of a stack of layers. The first layer 2; 102; 202, the layer of ferroelectric material 5; 105; 205 and the second layer 7; 107; 207 form the different layers of this stack.

In the first embodiment visible in FIG. 2, the stack extends along an axis z. The different layers extend in parallel to each other (and in parallel to a support layer 10 represented in FIGS. 4 to 7). The axis z is here perpendicular to the plane of the different layers of the stack forming the ferroelectric storage device 1 according to the first embodiment.

As is represented in FIGS. 4 to 7, the support layer 10 comprises, for example, at least one via 11 for connecting the ferroelectric storage device 1 to lower metal levels (e.g. made of copper Cu). The via 11 is made of tungsten W, for example.

Alternatively, the first layer can be disposed on a substrate not represented or on another layer.

In the second and third embodiments, as described in more detail hereinafter with associated manufacturing methods, the ferroelectric storage device 100; 200 is formed in a cavity 150; 250. This cavity 150; 250 is for example formed in a support layer 110; 210. Here, a single cavity 150; 250 is formed in the support layer 110; 210. In other words, the cavity 150; 250 forms a part of the support layer which has an overall “U”-shaped profile (as will be seen later, the side limbs of the “U”-shape are here tilted relative to the base of the “U”-shape). In these embodiments, the different layers of the ferroelectric storage device 100; 200 have a similar shaped profile to the part 150; 250 with a “U” shaped profile of the support layer 110; 210.

This support layer 110; 210 is for example made of a dielectric material. The support layer may comprise a plurality of sub-layers. For example, the support layer may comprise another layer of dielectric material formed under the layer comprising silicon oxide SiO₂. This further layer comprises, for example, silicon nitride SiN or silicon carbonitride SiCN.

The cavity 150; 250 comprises a bottom wall 152; 252 and a side wall 155; 255, 257. The bottom wall 152; 252 corresponds to the base of the “U” shape and the side wall 155; 255, 257 corresponds to the side branches of the “U” shape. The side wall 155; 255, 257 forms a first non-zero tilt angle α; β relative to an axis z, corresponding to a direction normal to the bottom wall 152; 252.

In the second embodiment represented in FIG. 8, the first tilt angle α is, for example, between 13 and 50 degrees, for example between 15 and 35 degrees. In an embodiment, this first tilt angle α is in the order of 18 degrees.

In the third embodiment visible in FIG. 14, the side wall 255 of the cavity 250 comprises a first portion 255a and a second portion 255b. The first portion 255a forms a first non-zero tilt angle α relative to the axis z. The second portion 255b forms a second non-zero tilt angle β relative to the axis z. In other words, in this third embodiment, the side wall 255 of the cavity 250 has a break of slope, with the first tilted portion 255a tilted according to the first tilt angle α and the second portion 255b tilted according to the second tilt angle β.

The second tilt angle β is greater than the first tilt angle α.

The second tilt angle β is, for example, between 15 and 70 degrees, for example between 20 and 40 degrees. In an embodiment, this second tilt angle β is in the order of 20 degrees.

In these second and third embodiments, the stack (forming the storage device 100; 200) extends from the bottom wall 152; 252 and the side wall 155; 255. This stack then comprises several parts: one extending from the bottom wall 152; 252 and another extending from the side wall 155; 255 (in the third embodiment, one part extends from the first portion 255a of the side wall 255 and another part extends from the second portion 255b of the side wall 255). For the part formed on the bottom wall 152; 252, the different layers of the stack extend in parallel to each other. The same applies to the part extending from the side wall 155; 255 (the different layers of the stack also extend in parallel to each other on this side wall 155; 255).

Alternatively, the side wall of the cavity could of course comprise a number greater than 2 of portions forming distinct angles relative to a direction normal to the bottom wall. In other words, the side wall of the cavity may have a plurality of breaks of slope.

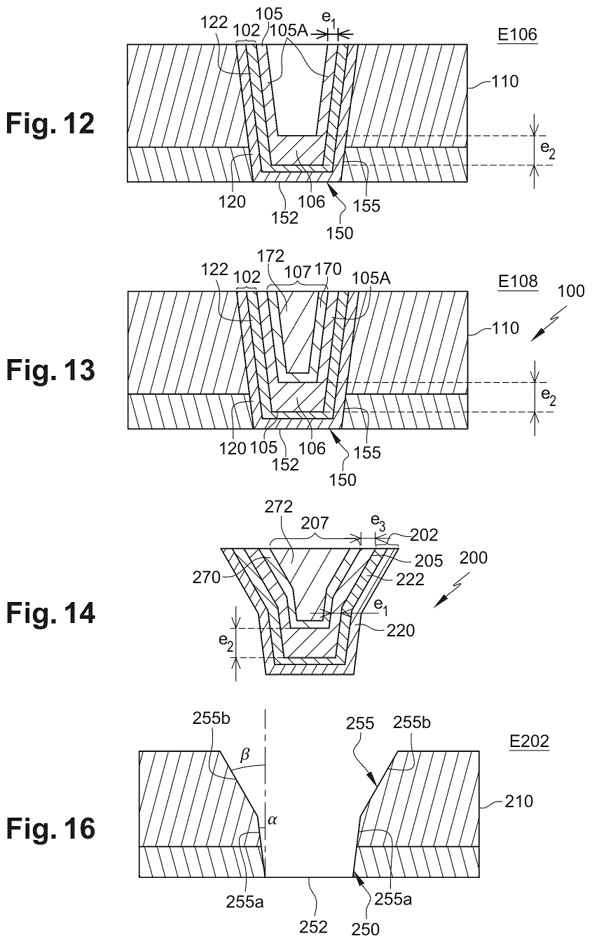

In practice, as is visible in FIGS. 12 and 18, the contact surface between the first layer 102; 202 and the layer of ferroelectric material 105; 205 is parallel to the contact surface between the first layer 102; 202 and the cavity 150; 250. In the present description, the wording “contact surface” refers to the interface between the two layers concerned.

More particularly here, the contact surface between the first layer 102; 202 and the layer of ferroelectric material 105; 205 is parallel at all points to the contact surface between the first layer 102; 202 and the cavity 150; 250. In other words, each portion of the contact surface between the first layer 102; 202 and the layer of ferroelectric material 105; 205 is parallel to the portion of the contact surface between the first layer 102; 202 and the cavity 150; 250 facing it. In other words still, the first layer 102; 202 and the layer of ferroelectric material 105; 205 extend parallel to each other without any folded portion of either layer (of the first layer or of the layer of ferroelectric material).

Each of the layers forming the ferroelectric storage device 1; 100; 200 is now described.

The first layer 2; 102; 202 is formed of an inert conductive material. This first layer 2; 102; 202 comprises, for example, a metal material.

According to a first example (not represented), the first layer comprises a single layer. The conductive material of this single layer comprises, for example, titanium nitride TiN. Alternatively, the conductive material may be tantalum nitride TaN or tungsten W. Still alternatively, other conductive materials may be used (and in particular metal nitride more generally).

As is visible in a second example represented in FIGS. 2, 8 and 14, the first layer 2; 102; 202 is herein in the form of a two-layer structure. It comprises herein a first sub-layer 20; 120; 220 and a second sub-layer 22; 122; 222.

The second sub-layer 22; 122; 222 is disposed on the first sub-layer 20; 120; 220.

The first sub-layer 20; 120; 220 comprises a metal conductive material. In an embodiment, it comprises titanium Ti or tantalum nitride TaN.

The first sub-layer 20; 120; 220 has a thickness of between 3 and 20 nanometers (nm). In an embodiment, this thickness is between 5 and 10 nm.

This first sub-layer 20; 120; 220 acts both as a protective layer and as a contact layer for electrically connecting the device 1; 100; 200 to its electronic control and read circuit.

The second sub-layer 22; 122; 222 is disposed on the first sub-layer 20; 120; 220. It is in direct contact with the layer of ferroelectric material 5; 105; 205. In other words, the second sub-layer 22; 122; 222 extends between the first sub-layer 20; 120; 220 and the layer of ferroelectric material 5; 105; 205.

The second sub-layer 22; 122; 222 is formed of a conductive material comprising a transition metal. This conductive material is, for example, titanium nitride TiN. Alternatively, it may be other conductive materials such as tantalum Ta or tungsten W.

For example, when the second sub-layer 22; 122; 222 comprises titanium nitride, the first sub-layer 20; 120; 220 is formed of a conductive material such as titanium Ti.

Alternatively, when the second sub-layer 22; 122; 222 comprises tantalum, the first sub-layer 20; 120; 220 is formed, for example, of tantalum nitride TaN.

Still alternatively, when the second sub-layer 22; 122; 222 comprises tungsten, the first sub-layer 20; 120; 220 is formed of a conductive material of titanium Ti.

Herein, the thickness of the second sub-layer 22; 122; 222 is between 10 and 100 nm. In an embodiment, this thickness is between 5 and 10 nm.

Alternatively, the first layer may comprise a semiconductor material. This semiconductor material comprises silicon, for example.

The layer of ferroelectric material 5; 105; 205 is disposed on the first layer 2; 102; 202. Alternatively, the layer of ferroelectric material can be deposited onto another layer previously present on the first layer.

This layer of ferroelectric material 5; 105; 205 is based, for example, on hafnium dioxide HfO₂. In the present description, by the term “based on”, it is meant that the layer concerned comprises more than 50% of the element mentioned after this term (for example herein, this means that the layer of ferroelectric material 5; 105; 205 comprises more than 50% hafnium dioxide).

Alternatively, hafnium dioxide can be doped with a doping element. In the present description, the expression “doping” of a layer relates to the introduction into the material of the layer concerned of atoms of another material referred to as a “doping element”.

Here, in an embodiment, the used doping element is silicon Si. In the case of silicon, the layer of ferroelectric material based on hafnium dioxide is for example exposed to a dose of dopant of between 1.10¹⁴ cm⁻² and 1.10¹⁵ cm⁻² in order to obtain a presence of between 0.7 and 7% of silicon atoms in the layer of ferroelectric material. In an embodiment, the dose of dopant is between 0.3.10¹⁵ cm⁻² and 1.10¹⁵ cm⁻².

Alternatively, other doping elements can be used, such as aluminium Al, germanium Ge, gadolinium Gd, yttrium Y, lanthanum La, scandium Sc or nitrogen N.

Still alternatively, the layer of ferroelectric material may comprise an alloy of the form HfₓZr₁₋ₓO₂, where 0<x<1. For example, it is possible to use a ternary HfZrO₂ alloy (for example Hf_{0.5}Zr_{0.5}O₂) as the ferroelectric material. Still alternatively, the layer of ferroelectric material can be made of aluminium scandium nitride (AlScN).

As is visible in FIGS. 2, 8 and 14, the layer of ferroelectric material 5; 105; 205 comprises at least a first part 5A; 105A; 205A and a second part 6; 106; 206. In the case of the ferroelectric storage device 200 according to the third embodiment, the layer of ferroelectric material 205 comprises a third part 205B.

In the first embodiment of the ferroelectric storage device 1 (visible in FIG. 2), the second part 6 of the layer of ferroelectric material 5 has at least two sub-portions 6B, 6C flanking the first part 5A. In other words, each of the two sub-portions 6B, 6C is disposed on either side of the first part 5A of the layer of ferroelectric material 5.

In the second embodiment of the ferroelectric storage device 100 (represented in FIG. 8), the first part 105A extends along the side wall 155 of the cavity 150 while the second part 106 extends along the bottom wall 152 of the cavity 150.

In the third embodiment of the ferroelectric storage device 200 (illustrated in FIG. 14), the first part 205A extends along a first portion 255a of the side wall 255 of the cavity 250, the second part 206 extends along the bottom wall 252, and the third part 205B of the layer of ferroelectric material extends along the second portion 255b of the side wall 255 of the cavity 250.

Beneficially, according to an embodiment of the invention, the first part 5A; 105A; 205A has a first thickness e₁ and the second part 6; 106; 206 has a second thickness e₂. In the present invention, the thickness of a part of a layer is defined as the distance separating the two faces of the part of the layer concerned. In other words, the thickness corresponds to the characteristic dimension of the layer concerned in a direction parallel to a direction normal to the faces of the part of the layer concerned.

For example, in the case of FIG. 2, the layer of ferroelectric material 5 has a first face 10A and a second face 10B. Herein, the face 10A is in contact with the first layer 2 and the face 10B is in contact with the second layer 7.

Here, the first thickness e₁ and the second thickness e₂ are distinct. In other words, the layer of ferroelectric material 5; 105; 205 has a non-uniform thickness. In other words, the layer of ferroelectric material 5; 105; 205 has a variable thickness.

Differences in thickness are essential characteristics of the ferroelectric storage device for obtaining different polarisation states.

Thus, by virtue of an embodiment of the invention, the different thicknesses used for the layer of ferroelectric material introduce a non-uniformity in the ferroelectric properties of the layer of ferroelectric material. This non-uniformity of properties especially makes it possible to increase differences between the voltage ranges to be applied to encode the information in the different intermediate polarisation states. This makes it possible to avoid overlapping between the voltage ranges concerned and therefore to unambiguously identify the intermediate polarisation states related to the stored information.

In order to obtain very distinct polarisation states (i.e. with no overlap between the ranges of voltages to be applied to reach them), the ratio of the second thickness e₂ to the first thickness e₁ is, in an embodiment, between 2 and 4.

In practice, the first thickness e₁ is, for example, between 3 and 7 nm. In an embodiment, this first thickness e₁ is in the order of 4 nm.

The second thickness e₂ is, for example, between 8 and 17 nm. In an embodiment, this second thickness e₂ is in the order of 10 nm.

Here, the second thickness e₂ is therefore greater than the first thickness e₁. This means that a higher voltage will have to be applied to enable the information stored in the intermediate polarisation state associated with the second thickness e₂ (compared with the first thickness e₁) to be encoded.

The thickness ranges considered in an embodiment of the invention make it possible to enhance non-uniformities of the ferroelectric properties of the layer of ferroelectric material, so as to make it possible to store information on different intermediate polarisation states and to encode this information by distinguishing distinctly between these different states.

Furthermore, in a plane orthogonal to the direction for defining the thickness, a surface of the first part 5A; 105A; 205A is defined at one of the faces of the layer of ferroelectric material 5; 105; 205. It is also possible to define the total surface area of the layer of ferroelectric material 5; 105; 205 as the surface area of one of the faces of the layer of ferroelectric material 5; 105; 205. In other words, the surface area of the first part 5A; 105A; 205A corresponds to a part of the total surface area of the layer of ferroelectric material 5; 105; 205.

Beneficially according to an embodiment of the invention, the first part 5A; 105A; 205A has a surface area of at least 15% of the total surface area of the layer of ferroelectric material 5; 105; 205. In other words, the surface area of the first part 5A; 105A; 205A represents at least 15% of the total surface area of the layer of ferroelectric material 5; 105; 205.

Thus, beneficially according to an embodiment of the invention, non-uniformities (associated with differences in thickness) in the layer of ferroelectric material are not manufacturing artefacts. The fact that the parts associated with the different thicknesses have large surface areas ensures that the polarisation states are quite distinct (and therefore that there is no overlap between the voltage ranges to be applied to access the different polarisation states).

As shown in FIGS. 2, 8 and 14, the second layer 7; 107; 207 is disposed on the layer of ferroelectric material 5; 105; 205.

This second layer 7; 107; 207 comprises, for example, a conductive material. This is especially a metal material.

According to a first example (not represented), the second layer comprises a single layer. The conductive material of this single layer comprises, for example, titanium nitride TIN. Alternatively, the conductive material may be tantalum nitride TaN or tungsten W. Still alternatively, other conductive materials may be used (and in particular metal nitride more generally).

As is visible in FIGS. 2, 8 and 14, the second layer 7; 107; 207 is herein in the form of a two-layer structure. It comprises a first sub-layer 70; 170; 270 and a second sub-layer 72; 172; 272.

The second sub-layer 72; 172; 272 of the second layer 7; 107; 207 is disposed on the first sub-layer 70; 170; 270 associated therewith.

The second sub-layer 72; 172; 272 is formed of a conductive material comprising a transition metal. This conductive material is, for example, titanium nitride TiN. Alternatively, it may be other conductive materials such as tantalum nitride TaN or tungsten W.

The second sub-layer 72; 172; 272 has a thickness of between 10 and 200 nm.

This second sub-layer 72; 172; 272 acts both as a protective layer and as a contact layer for electrically connecting the device 1; 100; 200 to its electronic control and read circuit.

The first sub-layer 70; 170; 270 is disposed on the layer of ferroelectric material 5; 105; 205. It is in direct contact with the layer of ferroelectric material 5; 105; 205. In other words, the first sub-layer 70; 170; 270 of the second layer 7; 107; 207 extends between the second sub-layer 72; 172; 272 and the layer of ferroelectric material 5; 105; 205.

The second sub-layer 72; 172; 272 comprises a metal conductive material. In an embodiment, it comprises titanium Ti or tantalum Ta.

For example, when the second sub-layer 72; 172; 272 comprises titanium nitride, the first sub-layer 70; 170; 270 is formed of a conductive material such as titanium Ti.

Alternatively, when the second sub-layer 72; 172; 272 comprises tantalum nitride, the first sub-layer 70; 170; 270 is formed of a conductive material such as tantalum Ta.

Still alternatively, when the second sub-layer 72; 172; 272 comprises tungsten, the first sub-layer 70; 170; 270 is formed of a conductive material selected from titanium Ti or tantalum Ta.

Herein, the thickness of the first sub-layer 70; 170; 270 is between 3 and 20 nm.

In practice, in the case of an OxRAM (Oxide Resistive RAM) type memory, when this two-layer structure is used for the second layer 7; 107; 207, the first sub-layer 70; 170; 270 also has the feature of being a layer which will allow the creation of oxygen vacancies in the layer of ferroelectric material 5; 105; 205 (when this first sub-layer 70; 170; 270 is in contact with the layer of ferroelectric material 5; 105; 205). In this case, the first sub-layer 70; 170; 270 comprises a conductive material selected from titanium Ti or tantalum Ta, and the second sub-layer 72; 172; 272 comprises a titanium nitride TiN or a tantalum nitride TaN (so as to form a protective layer). The creation of these oxygen vacancies then improves performance of the ferroelectric storage device by facilitating oxygen exchanges with the layer of ferroelectric material.

In the case of a memory of the FeRAM type, the second layer 7; 107; 207 comprises, for example, a metal nitride or a metal which does not oxidise (such as tungsten W or ruthenium Ru).

In the case of an FTJ type memory, the structure used is that of a FeRAM type memory with the introduction of a layer comprising a dielectric material between the layer of ferroelectric material 5; 105; 205 and the second layer 7; 107; 207. The dielectric material is, for example, a dielectric oxide such as aluminium oxide Al₂O₃ or silicon dioxide SiO₂.

Alternatively, the second layer may comprise a semiconductor material. This semiconductor material comprises silicon, for example.

Beneficially according to an embodiment of the invention, the ferroelectric storage device comprises a layer of ferroelectric material of variable thickness. This variability in thickness results in non-uniformity in the ferroelectric properties of the ferroelectric storage device. This non-uniformity of properties especially makes it possible to increase differences between the voltage ranges to be applied to encode information in the different intermediate polarisation states.

In other words, by virtue of the non-uniformity created in the layer of ferroelectric material (due to thickness variability), differences between the intermediate polarisation states are created.

Alternatively, the layer of ferroelectric material may comprise more than three distinct thicknesses. This can especially be a continuous variation in thickness.

This invention also relates to a method for manufacturing a ferroelectric storage device 1; 100; 200.

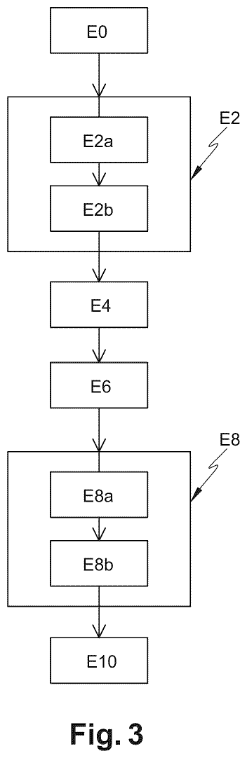

FIGS. 3 to 7 relate to a first embodiment of this manufacturing method in accordance with the invention. This first embodiment of the method for manufacturing enables manufacture of the ferroelectric storage device 1 represented in FIG. 2.

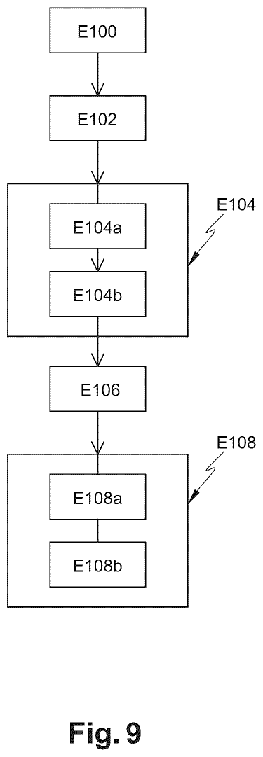

FIGS. 9 to 13 relate to a second embodiment of this manufacturing method in accordance with the invention. This second embodiment of the method for manufacturing enables manufacture of the ferroelectric storage device 100 represented in FIG. 8.

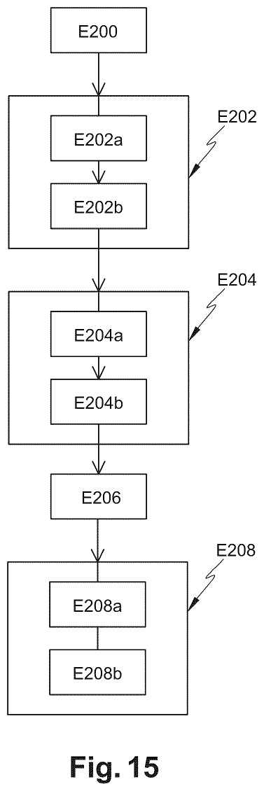

FIGS. 15 to 19 relate to a third embodiment of the manufacturing method in accordance with the invention. This third embodiment of the method for manufacturing enables manufacture of the ferroelectric storage device 200 represented in FIG. 15.

FIG. 3 represents, in the form of a flow chart, an example of the manufacturing method according to the first embodiment.

As is visible in this figure, the manufacturing method comprises first of all a step EO of providing a support layer 10 on which the ferroelectric storage device 1 will be formed. As previously indicated, this support layer 10 is provided with at least one via 11 for connecting the ferroelectric storage device 1 to lower metal levels.

Alternatively, this step can be a step of providing a substrate.

The manufacturing method then continues with a step E2 of depositing the first layer 2. The purpose of this step is therefore to form the first layer 2 on the support layer 10 (or on a substrate not represented).

This is a conformal deposition of the first layer 2. In this description, by “conformal deposition”, it is meant a deposition carried out in such a way that the layer has a substantially constant thickness at any point. In this description, by “substantially constant», it is meant a thickness that does not vary by more than 20%, for example by more than 10% and such as by more than 5%.

As previously indicated, the first layer 2 herein comprises a first sub-layer 20 and a second sub-layer 22.

Step E2 of depositing the first layer 2 therefore comprises two sub-steps: a first sub-step E2a of depositing the first sub-layer 20 and a second sub-step E2b of depositing the second sub-layer 22.

The first sub-layer 20 is therefore first conformally deposited onto the support layer 10 (or onto a substrate not represented). In practice, the first sub-layer 20 is formed, for example, by sputtering in a vacuum deposition chamber. In the case where the first sub-layer 20 is formed of titanium nitride, this is a reactive sputtering.

Alternatively, the first sub-layer can be formed by chemical vapour deposition.

Then the second sub-layer 22 of the first layer 2 is conformally deposited onto the first sub-layer 20. The second sub-layer 22 is formed, for example, by sputtering in a vacuum deposition chamber. In practice, the second sub-layer 22 of the first layer 2 is formed in the same deposition chamber as the first sub-layer 20 of the first layer 2.

If the second sub-layer 22 is formed of titanium nitride, this is a reactive sputtering.

Alternatively, the first layer 2 can be deposited using an Atomic Layer Deposition (ALD) method.

The method then continues with step E4 of depositing the layer of ferroelectric material 5 onto the first layer 2. More particularly, the layer of ferroelectric material 5 is deposited onto the second sub-layer 22 of the first layer 2. This step E4 is represented in FIG. 4.

Herein this is a conformal deposition of the layer of ferroelectric material 5 onto the first layer 2.

Herein, deposition step E4 is, for example, implemented in such a way that the layer of ferroelectric material has a thickness e₂.

In practice, the layer of ferroelectric material 5 is deposited by an atomic layer deposition (ALD) method.

Alternatively, the layer of ferroelectric material can be deposited by sputtering. Still alternatively, the layer of ferroelectric material may be deposited by a Physical vapour Deposition (PVD) method. Still alternatively, the layer of ferroelectric material can be deposited by an Ion Beam Deposition (IBD) method.

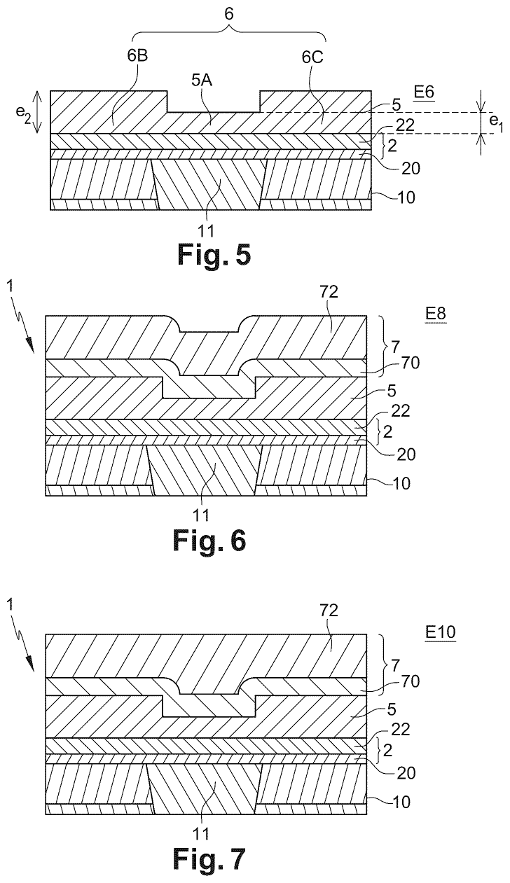

Then, as shown in FIG. 3, the method continues with a step E6 of removing a portion of the layer of ferroelectric material 5 formed in step E4. This step E6 is represented in FIG. 5.

This removal step then makes it possible to form the first part 5A and the second part 6 of the layer of ferroelectric material 5. In other words, the portion removed of the layer of ferroelectric material 5 is such that the remaining part (of layer of ferroelectric material 5) has a thickness e₁. This remaining portion then corresponds to the first part 5A of the layer of ferroelectric material 5.

In practice, this removal step E6 is carried out by lithography and then by etching. It is, for example, implemented by photolithography.

Thus, by virtue of this removal step, the layer of ferroelectric material comprises the first part 5A having the first thickness e₁ and the second part 6 having the second thickness e₂. As previously indicated, the first thickness e₁ and the second thickness e₂ are distinct.

As previously indicated, the second thickness e₂ is greater than the first thickness e₁. This means that a higher voltage will have to be applied to encode the information stored in the intermediate polarisation state associated with the second part 6 (compared with the first part 5A).

The method then continues, in step E8, with depositing the second layer 7. This step E8 is represented in FIG. 6.

The second layer 7 is formed on the layer of ferroelectric material 5 obtained at the end of step E6.

Depositing the second layer 7 is also conformally implemented.

As previously indicated, the second layer 7 herein comprises a first sub-layer 70 and a second sub-layer 72.

Step E8 of the second layer 7 therefore herein comprises two sub-steps: a first sub-step E8a of depositing the first sub-layer 70 and a second sub-step E8b of depositing the second sub-layer 72.

The first sub-layer 70 is therefore first conformally deposited onto the layer of ferroelectric material 5. In practice, the first sub-layer 70 is formed, for example, by sputtering in a vacuum deposition chamber. In the case where the first sub-layer 70 is formed of titanium nitride, this is a reactive sputtering process.

Alternatively, the first sub-layer can be formed by chemical vapour deposition.

Then the second sub-layer 72 of the second layer 7 is conformally deposited onto the first sub-layer 70. The second sub-layer 72 is formed, for example, by sputtering in a vacuum deposition chamber. In practice, the second sub-layer 72 of the second layer 7 is formed in the same deposition chamber as the first sub-layer 70 of the second layer 7.

In the case where the second sub-layer 72 is made of titanium nitride, this is a reactive sputtering process.

As is visible in FIG. 6, as the layer of ferroelectric material 5 comprises the first part 5A with a thickness e₁ smaller than the second part 6 with a thickness e₂, when the second layer 7 is deposited, the latter does not have a planar free surface.

The manufacturing method then comprises a planarisation step E10. This step E10 consists in planarising and making uniform the surface of the second layer 7. This step E10 is represented in FIG. 7.

In practice, this step E10 is, for example, implemented by Chemical Mechanical Polishing (CMP).

This planarisation step is particularly beneficial because, by virtue of uniformity of the surface of the second layer, it improves electrical performance of the ferroelectric storage device and ensures better quality interconnections.

Finally, at the end of the manufacturing method according to this first embodiment, the resulting ferroelectric storage device 1 comprises a layer of ferroelectric material having variable thickness. This variability in thickness makes it possible to introduce non-uniformity into the ferroelectric properties of the layer of ferroelectric material. This non-uniformity of properties especially makes it possible to increase differences between the voltage ranges to be applied to store the information in the different intermediate polarisation states. This makes it possible to avoid overlap between the voltage ranges concerned and therefore to unambiguously identify the intermediate polarisation states related to the stored information.

The ferroelectric storage device 1 obtained by the manufacturing method according to this first embodiment has a so-called “planar” architecture, with a stack of layers parallel to each other. This configuration has the benefit of being easy to implement, especially as the depositions of the different layers can be made conformally or not.

According to one alternative implementation of this first embodiment, the method can comprise, between step E4 of depositing the layer of ferroelectric material and step E6 of removing a portion of the layer of ferroelectric material, a step of implanting a doping element in the layer of ferroelectric material formed in step E4. This step enables the layer of ferroelectric material to be doped with the doping element.

In practice, the implantation step is carried out, for example, in a reactor different from the deposition chamber for the first layer and the layer of ferroelectric material.

This is, for example, a step of ionically implanting silicon (which is the doping element) into the layer of ferroelectric material. The implantation doses are, for example, between 1.10¹⁴ cm⁻² and 1.10¹⁵ cm⁻². In an embodiment, the implantation dose is between 0.3. 10¹⁵ cm⁻² and 1.10¹⁵ cm⁻².

FIG. 9 represents, in the form of a flow chart, an example of the manufacturing method according to the second embodiment.

As is visible in this figure, the manufacturing method first comprises a step E100 of providing a support layer 110.

The manufacturing method then continues in step E102, during which the cavity 150 (in which the ferroelectric storage device 100 will be formed) is formed. A single cavity 150 is herein formed. FIG. 10 illustrates this step E102.

This step E102 is carried out by anisotropic etching to form the bottom wall 152 and the side wall 155 of the cavity 150. It is for example here dry chemical etching.

As previously described, the side wall 155 of the cavity 150 is made in such a way as to form the first tilt angle α relative to the axis z parallel to a direction normal to the bottom wall 152.

The side wall 155 thus forms a first non-zero tilt angle α relative to an axis z, corresponding to a direction normal to the bottom wall 152.

As is visible in FIG. 9, the manufacturing method continues, in step E104, with depositing the first layer 102. FIG. 11 illustrates this step E104.

This first layer 102 is deposited in the cavity 150. More particularly, the first layer 102 is deposited along the bottom wall 152 and the side wall 155 of the cavity 150. The first layer 102 therefore has the shape of the cavity 150.

Depositing the first layer 102 is herein conformally carried out. For example, the first layer 102 may be formed by an Atomic Layer Deposition (ALD) method.

As previously indicated, the first layer 102 herein comprises a first sub-layer 120 and a second sub-layer 122.

Step E104 of depositing the first layer 102 therefore comprises two sub-steps: a first sub-step E104a of depositing the first sub-layer 120 and a second sub-step E104b of depositing the second sub-layer 122.

The first sub-layer 120 is therefore first conformally deposited in the cavity 150 (step E104a). In practice, the first sub-layer 20 is for example formed by an atomic layer deposition (or ALD) method or by chemical vapour deposition.

Alternatively, the first sub-layer 120 may be formed by sputtering in a vacuum deposition chamber. In the case where the first sub-layer 120 is formed of titanium nitride, this is a reactive sputtering process.

Then, the second sub-layer 122 of the first layer 102 is conformally deposited onto the first sub-layer 120 (step E104b). The second sub-layer 122 is formed, for example, by sputtering in a vacuum deposition chamber. In practice, the second sub-layer 122 of the first layer 102 is formed in the same deposition chamber as the first sub-layer 120 of the first layer 102.

In the case where the second sub-layer 122 is made of titanium nitride, this is a reactive sputtering process.

The manufacturing method then continues with the step E106 of depositing the layer of ferroelectric material 105 onto the first layer 102. More particularly, the layer of ferroelectric material 105 is deposited onto the second sub-layer 122 of the first layer 102. This step E106 is represented in FIG. 12.

Beneficially in this second embodiment, depositing the layer of ferroelectric material 105 is non-conformally implemented. This means that the deposition is carried out in such a way that the thickness of the layer of ferroelectric material 105 is variable.

More particularly herein, the deposition is implemented so as to obtain a thickness e₂ of the ferroelectric material at the bottom wall 152 (thus forming the second part 106 of the layer of ferroelectric material 105) and to obtain a thickness e₁ of the ferroelectric material at the side wall 155 (thus forming the first part 105A of the layer of ferroelectric material 105).

In practice, the (non-conformal) deposition step E106 is implemented, for example, by a Physical vapour deposition (PVD) method.

Alternatively, the layer of ferroelectric material can be deposited by sputtering. Still alternatively, the layer of ferroelectric material can be deposited by an Ion Beam deposition (IBD) method.

This non-conformal deposition enables the layer of ferroelectric material 105 to be formed directly, with a first part 105A having the first thickness e₁ and a second part 106 having the second thickness e₂. As previously indicated, the second thickness e₂ is greater than the first thickness e₁. This implies that a higher voltage will be applied in order to encode the information stored in the intermediate polarisation state associated with the second part 106 (compared with the first part 105).

The method then continues, in step E108, with depositing the second layer 107. This step E108 is represented in FIG. 13.

The second layer 107 is formed on the layer of ferroelectric material 105 obtained at the end of step E106.

Depositing the second layer 107 is conformally made.

As previously indicated, the second layer 107 herein comprises a first sub-layer 170 and a second sub-layer 172.

Step E108 of depositing the second layer 107 therefore comprises two sub-steps: a first sub-step E108a of depositing the first sub-layer 170 and a second sub-step 108b of depositing the second sub-layer 172.

The first sub-layer 170 is therefore first conformally deposited onto the layer of ferroelectric material 105 (step E108a). In practice, the first sub-layer 170 is for example formed by sputtering in a vacuum deposition chamber. In the case where the first sub-layer 170 is formed of titanium nitride, this is a reactive sputtering process.

Alternatively, the first sub-layer can be formed by chemical vapour deposition.

And then, the second sub-layer 172 of the second layer 107 is conformally deposited onto the first sub-layer 170 (step E108b). As is visible in FIG. 13, the second sub-layer 172 is formed so as to fill all the remaining space in the cavity 150. This makes it possible to obtain a ferroelectric storage device 100 completely integrated into the cavity 150 and without any projection or recess formed relative to the surface of the support layer 110. The assembly formed by the support layer 110 into which the ferroelectric storage device 100 is integrated therefore has a uniform surface.

In practice, the second sub-layer 172 is for example formed by sputtering in a vacuum deposition chamber. In practice, the second sub-layer 172 of the second layer 107 is formed in the same deposition chamber as the first sub-layer 170 of the second layer 107.

In the case where the second sub-layer 172 is made of titanium nitride, this is a reactive sputtering process.

The ferroelectric storage device 100 then takes the form of a continuous stack of layers. In other words, the ferroelectric storage device 100 comprises a continuity in the layers it comprises.

In practice, although this is not visible in the appended figures, it is not excluded that the different layers of the ferroelectric storage device 100 are also deposited onto the front face (free surface opposite to the bottom wall 152) of the support layer. Thus, optionally, in order to ensure flatness and uniformity of the ferroelectric storage device 100 (and in particular of the free surface of the device 100), there can be provided a planarisation step, after step E108. This planarisation step is implemented, for example, by Chemical Mechanical Polishing (CMP). Any other adapted method can be used (especially masking methods).

This planarisation step is particularly beneficial because, by virtue of the uniformity of the surface of the device 100, it improves electrical performance of the ferroelectric storage device and ensures better quality interconnections.

Alternatively, an encapsulation step can be carried out after this planarisation step. Finally, a connection to the second layer can be implemented.

Thus, at the end of the manufacturing method according to this second embodiment, the resulting ferroelectric storage device 100 comprises a layer of ferroelectric material with variable thickness. As previously indicated, a variability in thicknesses makes it possible to introduce non-uniformities in the ferroelectric properties of the layer of ferroelectric material. This non-uniformity of properties especially makes it possible to increase differences between the voltage ranges to be applied to encode the information in the different intermediate polarisation states.

This avoids overlap between the voltage ranges concerned and therefore enables unambiguous identification of the intermediate polarisation states related to the encoded information.

In addition, the manufacturing method according to this second embodiment makes it possible to obtain a three-dimensional architecture of the ferroelectric storage device 100. This makes it possible especially to increase the surface area of the capacity of the ferroelectric storage device 100.

FIG. 15 represents, in the form of a flow chart, an example of the manufacturing method according to the third embodiment.

This third embodiment of the manufacturing method is similar to the second embodiment described previously. Therefore, only the differences relative to this second embodiment are described in detail below.

As is visible in FIG. 15, the manufacturing method first comprises a step E200 (similar to step E100) of providing a support layer 210.

The manufacturing method then continues in step E202, during which the cavity 250 (in which the ferroelectric storage device 200 will be formed) is formed. A single cavity 250 is herein formed. FIG. 16 illustrates this step E202.

The specificity of this third embodiment lies in forming the cavity 250, and more particularly in forming the side wall 255 of the cavity 250. Herein, step E202 actually comprises two sub-steps: a first sub-step E202a of forming a first portion 255a of the side wall 255 and a second sub-step E202b of forming a second portion 255b of the side wall 255.

The first sub-step E202a is implemented by isotropic etching to form the bottom wall 252 and the first portion 255a of the side wall 250. This is for example wet chemical etching.

The first portion 255a of the side wall 255 of the cavity 250 is formed so as to have the first tilt angle α relative to the axis z parallel to a direction normal to the bottom wall 252 (as during step E102 described previously).

The first portion 255a of the side wall 255 thus forms a first non-zero tilt angle α relative to an axis z, corresponding to a direction normal to the bottom wall 252.

The second sub-step E202b corresponds to an additional step of isotropically etching the cavity 255. More particularly, this second sub-step E202b is aimed at forming the second portion 255b of the side wall 255 of the cavity 250.

Here, the second portion 255b of the side wall 255 of the cavity 250 is formed, on the side wall 255, at the surface opposite to the bottom wall 252. This second portion 255b is made such that it forms a second tilt angle β relative to the axis z parallel to a direction normal to the bottom wall 252. In other words, the second portion 255b of the side wall 255 thus forms a non-zero second tilt angle β relative to an axis z, corresponding to a direction normal to the bottom wall 252.

Thus, at the end of step E202, the side wall 255 of the cavity 250 having a first portion 255a tilted by a first angle α relative to the axis z and a second portion 255b tilted by a second angle β relative to the axis z is formed. Here, this side wall 255 of the cavity 250 therefore has a break of slope, with the first tilted portion 255a tilted at the first tilt angle α and the second portion 255b tilted at the second tilt angle β. The side wall 255 has a sort of “Y” shape.

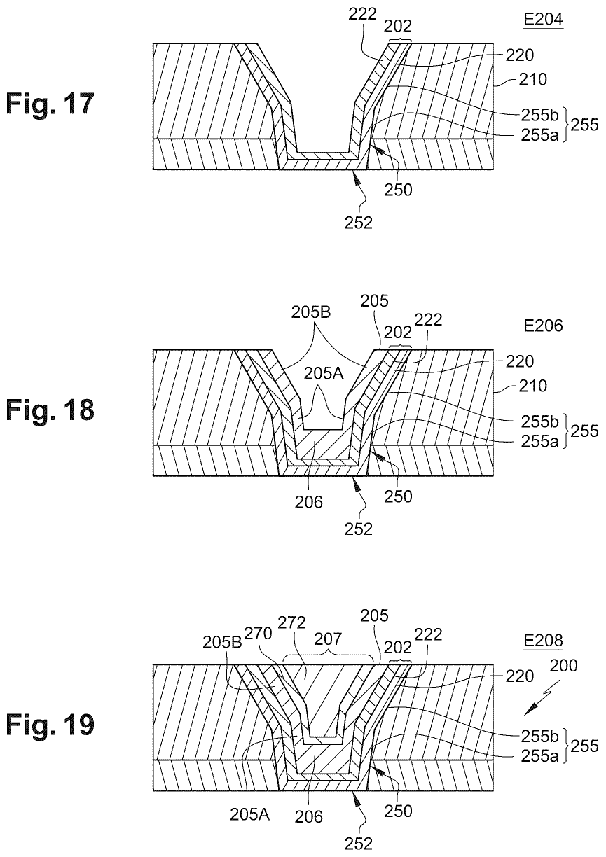

As is visible in FIG. 15, the manufacturing method continues, in step E204, with depositing the first layer 202. FIG. 17 illustrates this step E204. Step E204 is similar to step E104 described for the second embodiment.

This first layer 202 is deposited in the cavity 250. More particularly, the first layer 202 is deposited along the bottom wall 252 and the side wall 255 of the cavity 250.

Depositing the first layer 202 is herein conformally made.

As previously indicated, the first layer 202 herein comprises a first sub-layer 220 and a second sub-layer 222.

Step E204 of depositing the first layer 202 therefore comprises two sub-steps: a first sub-step E204a of depositing the first sub-layer 220 and a second sub-step E204b of depositing the second sub-layer 222.

The first sub-layer 220 is therefore first conformally deposited in the cavity 250 (step E204a). In practice, the first sub-layer 220 is for example formed by sputtering in a vacuum deposition chamber. In the case where the first sub-layer 220 is formed of titanium nitride, this is a reactive sputtering process.

Alternatively, the first sub-layer can be formed by chemical vapour deposition.

Then, the second sub-layer 222 of the first layer 202 is conformally deposited onto the first sub-layer 220 (step E204b). The second sub-layer 222 is formed, for example, by sputtering in a vacuum deposition chamber. In practice, the second sub-layer 222 of the first layer 202 is formed in the same deposition chamber as the first sub-layer 220 of the first layer 202.

In the case where the second sub-layer 222 is formed of titanium nitride, this is a reactive sputtering process.

The manufacturing method then continues with the step E206 of depositing the layer of ferroelectric material 205 onto the first layer 202. More particularly, the layer of ferroelectric material 205 is deposited onto the second sub-layer 222 of the first layer 202. This step E206 is represented in FIG. 18. Step E206 is similar to step E106 previously described for the second embodiment.

Beneficially in this second embodiment, depositing the layer of ferroelectric material 205 is non-conformally implemented. This means that the deposition is carried out in such a way that the thickness of the layer of ferroelectric material 205 is variable.

More particularly herein, the deposition is carried out so as to obtain a thickness e₂ of the ferroelectric material at the bottom wall 252, to obtain a thickness e₁ of the ferroelectric material at the first portion 255a of the side wall 255 and a thickness e₃ at the second portion 255b of the side wall 255 of the cavity 250. Herein, the thicknesses satisfy the following inequality: e₂>e₃>e₁.

In other words, the greatest thickness e₂ of ferroelectric material is formed at the bottom wall 252, an intermediate thickness e₃ is formed at the second portion 225b of the side wall 255 of the cavity 250 and the smallest thickness e₁ is formed at the first portion 255a of the side wall 255 of the cavity 250.

In practice, the (non-conformal) deposition step E206 is implemented, for example, by a physical vapour deposition (PVD) method.

Alternatively, the layer of ferroelectric material can be deposited by sputtering. Still alternatively, the layer of ferroelectric material can be deposited by an ion beam deposition (IBD) method.

This non-conformal deposition enables the layer of ferroelectric material 205 to be formed directly with a first part 205A which has the first thickness e₁ (smallest thickness), a second part 206 which has the second thickness e₂ (largest thickness) and a third part 205B which has the third thickness e₃.

These differences in thickness mean that a higher voltage will be applied to enable information stored in the intermediate polarisation state associated with the second part 206 to be encoded, an intermediate voltage to enable information stored in the intermediate polarisation state associated with the third part 205B to be encoded and finally a lower voltage to enable information stored in the intermediate polarisation state associated with the first part 205A to be encoded.

The method then continues, in step E208, with depositing the second layer 207. This step E208 is represented in FIG. 19. This step is similar to step E108 described previously for the second embodiment.

The second layer 207 is formed on the layer of ferroelectric material 205 obtained at the end of step E206.

Depositing the second layer 207 is conformally made.

As previously indicated, the second layer 207 can comprise a first sub-layer 270 and a second sub-layer 272.

Step E208 of depositing the second layer 207 therefore comprises two sub-steps: a first sub-step E208a of depositing the first sub-layer 270 and a second sub-step 208b of depositing the second sub-layer 272.

The first sub-layer 270 is therefore first conformally deposited onto the layer of ferroelectric material 205 (step E208a). In practice, the first sub-layer 270 is for example formed by sputtering in a vacuum deposition chamber. In the case where the first sub-layer 270 is formed of titanium nitride, this is a reactive sputtering.

Alternatively, the first sub-layer can be formed by chemical vapour deposition.

Then, the second sub-layer 272 of the second layer 207 is conformally deposited onto the first sub-layer 270 (step E208b). As is visible in FIG. 19, the second sub-layer 272 is formed so as to fill all the remaining space in the cavity 250. Hence, this makes it possible to obtain a ferroelectric storage device 200 which is fully integrated into the cavity 250 and without any projection or recess formed relative to the surface of the support layer 210. The assembly formed by the support layer 210 into which the ferroelectric storage device 200 is integrated therefore has a uniform surface.

In practice, the second sub-layer 272 is for example formed by sputtering in a vacuum deposition chamber. In practice, the second sub-layer 272 of the second layer 207 is formed in the same deposition chamber as the first sub-layer 270 of the second layer 207.

If the second sub-layer 272 is made of titanium nitride, this is a reactive sputtering process.

In practice, although this is not visible in the appended figures, it is not excluded that the different layers of the ferroelectric storage device 200 are also deposited onto the front face (free surface opposite to the bottom wall 252) of the support layer. Thus, optionally, in order to ensure the flatness and uniformity of the ferroelectric storage device 200 (and in particular of the free surface of the device 200), a planarisation step can be provided, after step E208. This planarisation step is carried out, for example, by Chemical Mechanical Polishing (CMP). Any other adapted method can be used (especially masking methods).

This planarisation step is particularly beneficial because, by virtue of making the surface of the device 1 uniform, it improves electrical performance of the ferroelectric storage device and ensures better quality interconnections.

Alternatively, an encapsulation step can be carried out after this planarisation step. Finally, connecting the second layer can be implemented.

The ferroelectric storage device 200 then takes the form of a continuous stack of layers. In other words, the ferroelectric storage device 200 comprises a continuity in the layers it comprises.

Thus, at the end of the manufacturing method according to this second embodiment, the resulting ferroelectric storage device 200 comprises a layer of ferroelectric material with variable thickness. As previously indicated, the variability of thicknesses makes it possible to introduce non-uniformity into the ferroelectric properties of the layer of ferroelectric material. This non-uniformity of properties especially makes it possible to increase differences between the voltage ranges to be applied to store the information in the different intermediate polarisation states. This makes it possible to avoid overlap between the voltage ranges concerned and therefore to unambiguously identify the intermediate polarisation states related to the stored information.

In addition, the manufacturing method according to this third embodiment makes it possible to obtain a three-dimensional architecture of the ferroelectric storage device 200. This makes it possible especially to increase the surface area of the capacity of the ferroelectric storage device 200.

### Applications

The ferroelectric storage device according to an embodiment of the invention finds a favoured application within the scope of FeRAM-type resistive memories.

It also finds a particular application within the scope of transistors, for example of the FeMFET («Ferroelectric-metal field effect transistor») type.

The ferroelectric storage device according to an embodiment of the invention can also be used within the scope of ferroelectric tunnel junctions (FTJs). In this case, an additional layer is added between the layer of ferroelectric material and the second layer. This additional layer comprises a dielectric material. This dielectric material is for example an aluminium oxide Al₂O₃.

In some of the applications mentioned (e.g. FeRAM or FTJ type memories), the first layer forms a first electrode (e.g. a lower electrode), the second layer forms a second electrode (e.g. an upper electrode) and the layer of ferroelectric material forms a memory layer.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements, components, compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A ferroelectric storage device comprising:
a first layer;
a second layer;
a layer of ferroelectric material which extends between the first layer and the second layer, the first layer having a constant thickness, the layer of ferroelectric material comprising a first part having a first thickness and a second part having a second thickness, the first thickness and the second thickness being distinct, and
a support layer having a cavity, the cavity comprising a bottom wall and a side wall, the side wall forming a tilt angle relative to a direction normal to the bottom wall, the first layer, the second layer and the layer of ferroelectric material being positioned in the cavity.

2. The ferroelectric storage device according to claim 1, wherein a ratio of the second thickness to the first thickness is between 2 and 4.

3. The ferroelectric storage device according to claim 1, wherein the first thickness is between 3 and 7 nanometers and the second thickness is between 12 and 17 nanometers.

4. The ferroelectric storage device according to claim 1, wherein the first part of the layer of ferroelectric material has a surface area of at least 15% of the total surface area of the layer of ferroelectric material.

5. The ferroelectric storage device according to claim 1, wherein the layer of ferroelectric material comprises hafnium dioxide or hafnium dioxide doped with a doping element or an alloy HfₓZr₁₋ₓO₂, with 0<x<1.

6. The ferroelectric storage device according to claim 1, wherein the cavity comprises a U-shaped profile, the first layer, the second layer and the layer of ferroelectric material being positioned in the cavity so that the first layer, the second layer and the layer of ferroelectric material have a similar shape profile to the cavity with a U-shaped profile.

7. The ferroelectric storage device according to claim 6, wherein the second part of the layer of ferroelectric material is positioned on the bottom wall of the cavity with a U-shaped profile and the first part of the layer of ferroelectric material is positioned on the side wall of the cavity with a U-shaped profile.

8. The ferroelectric storage device according to claim 1, wherein the side wall of the cavity comprising a first portion and a second portion, the first portion forming said first tilt angle relative to the direction normal to the bottom wall, the second portion forming a second tilt angle relative to the direction normal to the bottom wall, the layer of ferroelectric material comprises a third part having a third thickness, the third thickness being distinct from the first thickness and from the second thickness, the second portion of the layer of ferroelectric material being positioned on the bottom wall of the cavity, the first part of the layer of ferroelectric material being positioned on the first portion of the side wall of the cavity and the third part of the layer of ferroelectric material being positioned on the second portion of the side wall of the cavity.

9. The ferroelectric storage device according to claim 8, wherein the second tilt angle is greater than said first tilt angle.

10. The ferroelectric storage device according to claim 1, wherein the contact surface between the first layer and the layer of ferroelectric material is parallel to the contact surface between the first layer and the cavity.

11. The ferroelectric storage device according to claim 1, wherein the first layer forms a first electrode, the second layer forms a second electrode and the layer of ferroelectric material forms a memory layer.

12. A method for manufacturing a ferroelectric storage device comprising:
providing a support layer;
forming a cavity in the support layer, the cavity comprising a bottom wall and a side wall, the side wall forming a non-zero first tilt angle relative to a direction normal to the bottom wall,
depositing a first layer, the first layer having a constant thickness,
depositing a layer of ferroelectric material, the layer of ferroelectric material comprising a first part having a first thickness and a second part having a second thickness, the first thickness and the second thickness being distinct, and
depositing a second layer, the layer of ferroelectric material extending between the first layer and the second layer,
depositing the first layer, the layer of ferroelectric material and the second layer being implemented in the cavity formed, the second part of the layer of ferroelectric material being positioned on the bottom wall of the cavity and the first part of the layer of ferroelectric material being positioned on the side wall of the cavity.

13. The manufacturing method according to claim 12, comprising, prior to depositing the second layer, removing a portion of the layer of ferroelectric material, the first part of the layer of ferroelectric material being formed at a remaining portion associated with said portion removed.

14. The manufacturing method according to claim 12, wherein the side wall of the cavity comprising a first portion and a second portion, the first portion forming said first tilt angle relative to the direction normal to the bottom wall, the second portion forming a second tilt angle relative to the direction normal to the bottom wall, the layer of ferroelectric material comprises a third part having a third thickness, the third thickness being distinct from the first thickness and from the second thickness, the second portion of the layer of ferroelectric material being positioned on the bottom wall of the cavity, the first part of the layer of ferroelectric material being positioned on the first portion of the side wall of the cavity and the third part of the layer of ferroelectric material being positioned on the second portion of the side wall of the cavity.

15. The manufacturing method according to claim 12, wherein depositing the layer of ferroelectric material is conformally implemented.
